(19) United States
(12) Patent Application Publication
(10) Pub. No.: US 2022/0148999 A1
(43) Pub. Date: May 12, 2022

(54) SEMICONDUCTOR DEVICE

(71) Applicant: FUJI ELECTRIC CO., LTD., Kawasaki-shi (JP)

(72) Inventor: Mariko Maruyama, Matsumoto-city (JP)

(73) Assignee: FUJI ELECTRIC CO., LTD., Kawasaki-shi (JP)

(21) Appl. No.: 17/488,421

(22) Filed: Sep. 29, 2021

(30) Foreign Application Priority Data
Nov. 12, 2020 (JP) 2020-188725

(51) Int. Cl. H01L 23/00; H01L 23/495; H01L 23/24; H01L 25/07

(52) U.S. Cl. CPC H01L 24/48; H01L 23/49562; H01L 24/05; H01L 23/24; H01L 2924/13091; H01L 2224/4805; H01L 2224/05553; H01L 2224/48227; H01L 2924/13055; H01L 25/072

(57) ABSTRACT

A semiconductor device includes an insulated circuit board including a circuit pattern, a semiconductor chip on the circuit pattern, a wire connected to the semiconductor chip, an external connection terminal including a leg portion extending in a direction perpendicular to a front surface of the circuit pattern and a terminal portion electrically connected to the leg portion, and a case including a frame portion which surrounds an insulated circuit board and a beam portion bonded to an external connection terminal and overlapping at least a part of a wire in a plan view of the semiconductor device, and a sealing member with which the case is filled, which seals a front surface of the insulated circuit board, a semiconductor chip, the wire, and a back surface of the beam portion, and which is exposed in the plan view from a gap between a leg portion and the beam portion.

### CROSS-REFERENCE TO RELATED APPLICATION

This application is based upon and claims the benefit of priority of the prior Japanese Patent Application No. 2020-188725, filed on Nov. 12, 2020, the entire contents of which are incorporated herein by reference.

### BACKGROUND OF THE INVENTION

### 1. Field of the Invention

The embodiment discussed herein relates to a semiconductor device.

### 2. Background of the Related Art

Semiconductor devices include power devices. The power devices are insulated gate bipolar transistors (IGBTs), power metal oxide semiconductor field effect transistors (MOSFETs), or the like. Such a semiconductor device includes an insulated circuit board over which semiconductor chips including the above power devices are arranged. The insulated circuit board includes a ceramic board, a plurality of circuit patterns formed on the front surface of the ceramic board, and a metal plate formed on the back surface of the ceramic board. The semiconductor chips are bonded to determined circuit patterns. Furthermore, electrodes of a plurality of semiconductor chips or an electrode of a semiconductor chip and a circuit pattern are properly connected by a wire. In addition, with the semiconductor device the insulated circuit board over which these semiconductor chips are arranged is housed in a case. Input-output lead frames are integrally molded with a lid portion of the case. Lower end portions of the lead frames are properly bonded to the circuit patterns of the insulated circuit board. The insulated circuit board in the case is sealed with silicone gel (see, for example, Japanese Laid-open Patent Publication No. 04-242965).

When the above semiconductor device operates, the semiconductor chips generate heat and the temperature in the case rises. At this time the heated silicone gel expands. As a result, expansion pressure is applied from the silicone gel to the wires and the wires swing. As a result, wires which are swinging may come in contact with each other or a wire which is swinging may come in contact with a lead frame. This leads to a short circuit. Accordingly, the amount of the expansion of silicone gel relative to a rise in temperature is estimated in advance. Distance by which the wires swing on the basis of the amount of the expansion of silicone gel is taken into consideration. By doing so, the circuit patterns, the semiconductor chips, and the lead frames are arranged so that even when the wires swing, contact will not occur.

A rise in the temperature of the semiconductor device varies according to its usage conditions or usage environment. Accordingly, the degree of the expansion of silicone gel also depends on the usage conditions or usage environment of the semiconductor device and distance by which the wires swing varies. As a result, even if the circuit patterns, the semiconductor chips, and the lead frames are arranged so that even when the wires swing, contact will not occur, a wire may come in contact with another wire or a lead frame depending on the usage conditions or usage environment of the semiconductor device. This leads to a short circuit.

### SUMMARY OF THE INVENTION

According to an aspect, there is provided a semiconductor device including: an insulated circuit board including an insulating plate and a circuit pattern formed on a front surface of the insulating plate; a semiconductor chip disposed on a front surface of the circuit pattern; a wire connected to a front surface of the semiconductor chip; an external connection terminal including a leg portion having one end bonded to the front surface of the circuit pattern, extending perpendicularly to the front surface of the circuit pattern, and facing the wire in a first direction perpendicular to a second direction in which the wire extends, and a terminal portion electrically connected to an other end of the leg portion; a case including a frame portion which surrounds the insulated circuit board, and a beam portion bonded to the external connection terminal with a gap between the leg portion and the beam portion and overlapping at least a part of the wire in a plan view of the semiconductor device; and a sealing member with which the case is filled, which seals a front surface of the insulated circuit board, the semiconductor chip, the wire, and a back surface of the beam portion, and is exposed from the gap between the leg portion and the beam portion, in the plan view.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is an external view of a semiconductor device according to an embodiment (part 1);

FIGS. 2A and 2B are external views of the semiconductor device according to the embodiment (part 2);

FIG. 3 is a plan view of the semiconductor device according to the embodiment;

FIG. 4 illustrates an equivalent circuit of the function of the semiconductor device according to the embodiment;

FIG. 5 is a fragmentary plan view of the semiconductor device according to the embodiment;

FIG. 6 is a fragmentary sectional view of the semiconductor device according to the embodiment (part 1);

FIG. 7 is a fragmentary sectional view of the semiconductor device according to the embodiment (part 2);

FIG. 8 is a fragmentary sectional view of the semiconductor device according to the embodiment (part 3); and

FIG. 9 is another fragmentary plan view of the semiconductor device according to the embodiment.

### DETAILED DESCRIPTION OF THE INVENTION

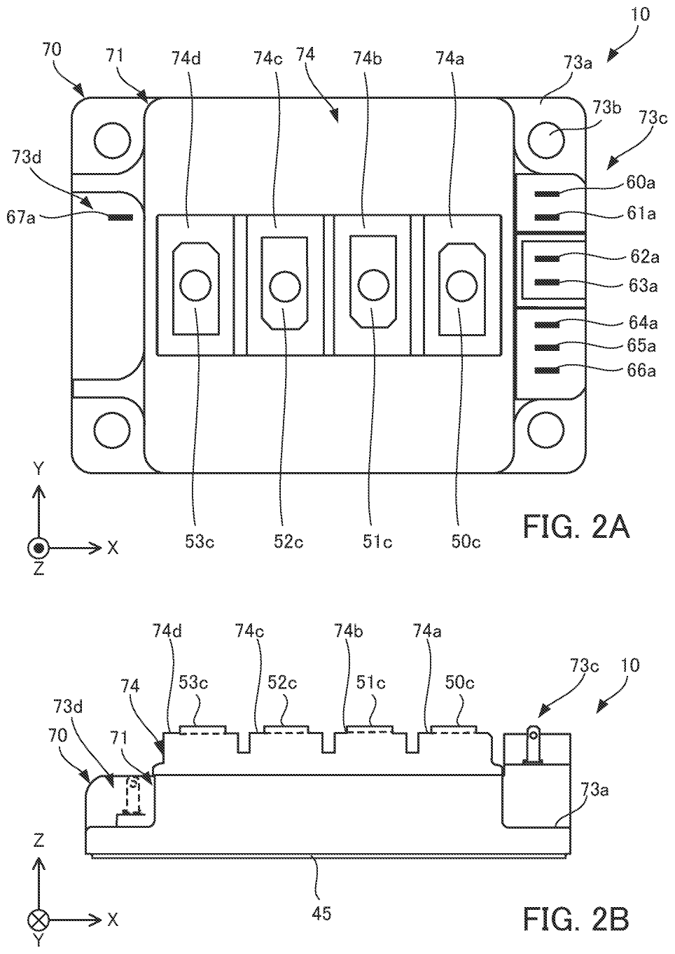

An embodiment will now be described in detail by reference to the accompanying drawings. In the following description a “front surface” or an “upper surface” indicates a surface of a semiconductor device 10 of FIG. 2A which faces this side of the paper (+Z direction). Similarly, an “upside” indicates the direction of this side of the paper (+Z direction) of the semiconductor device 10 of FIG. 2A. A “back surface” or a “lower surface” indicates a surface of the semiconductor device 10 of FIG. 2A which faces the other side of the paper (−Z direction) (the back surface is not illustrated in FIG. 2A). Similarly, a “downside” indicates the direction of the other side of the paper (-Z direction) of the semiconductor device 10 of FIG. 2A. A “side” indicates a surface of the semiconductor device 10 which connects the “front surface” or the “upper surface” and the “back surface” or the “lower surface”. For example, a “side” indicates a surface of the semiconductor device 10 of FIG. 2A which faces the upside, the downside, the left, or the light on the paper. These terms mean the same directions as needed in the other drawings. The “front surface,” the “upper surface,” the “upside,” the “back surface,” the “lower surface,” the “downside,” and the “side” are simply used as expedient representation for specifying relative positional relationships and do not limit the technical idea of the present disclosure. For example, the “upside” or the “downside” does not always mean the vertical direction relative to the ground. That is to say, a direction indicated by the “upside” or the “downside” is not limited to the gravity direction. Furthermore, in the following description a “main ingredient” indicates an ingredient contained at a rate of 80 volume percent (vol %) or more.

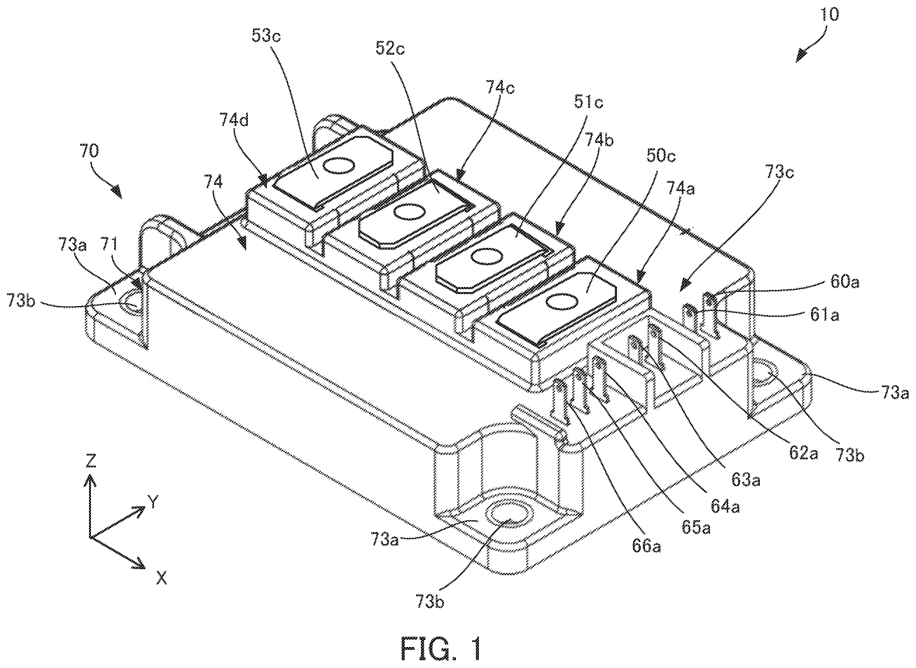

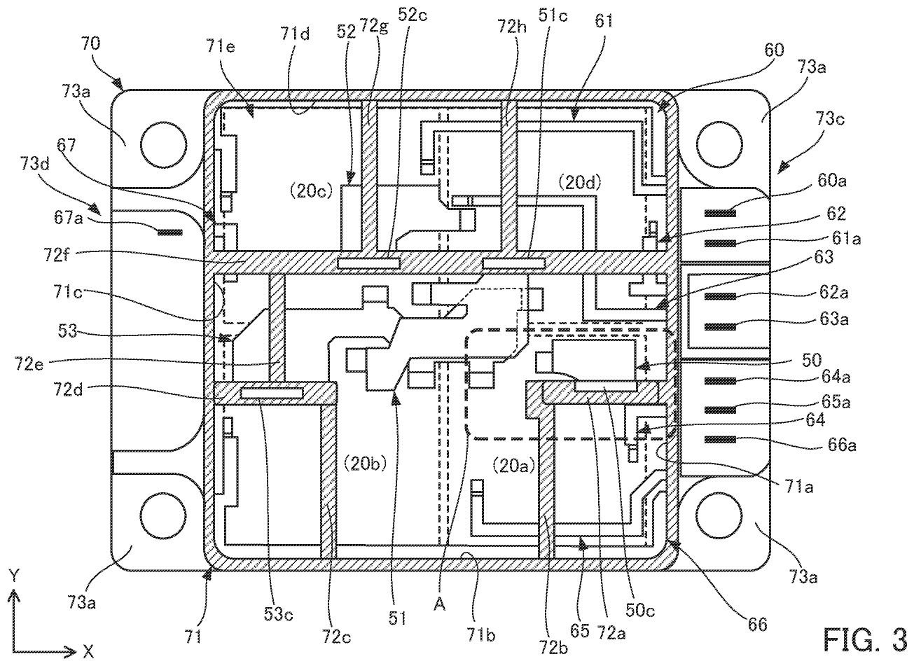

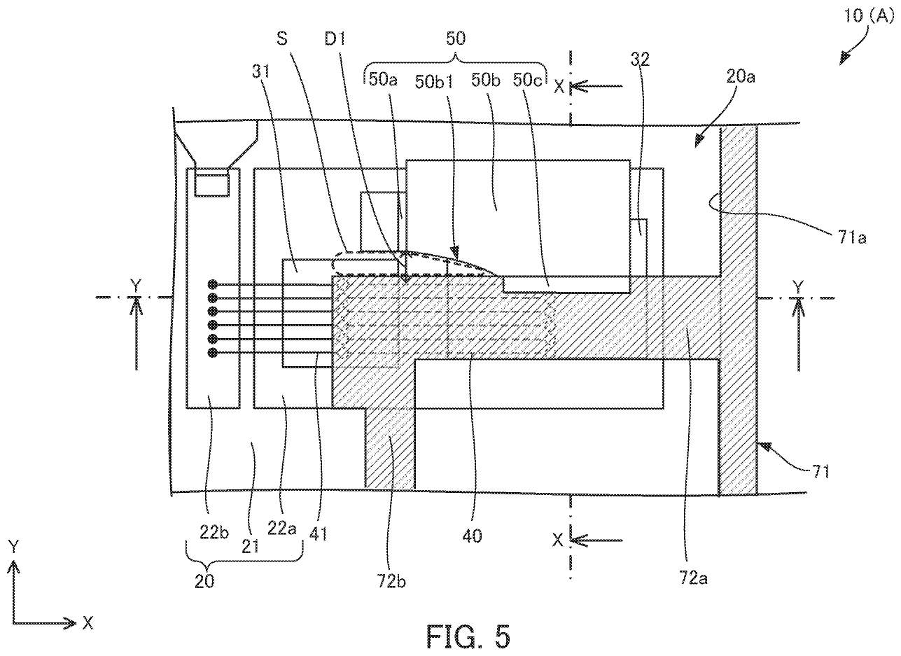

The semiconductor device 10 according to an embodiment will be described by the use of FIG. 1 through FIG. 3. FIG. 1 and FIGS. 2A and 2B are external views of the semiconductor device according to the embodiment. FIG. 3 is a plan view of the semiconductor device according to the embodiment. FIG. 1 is a perspective view of the semiconductor device 10. FIG. 2A is a plan view of the semiconductor device 10 and FIG. 2B is a side view of the semiconductor device 10. FIG. 3 is a plan view of the semiconductor device 10 in which a lid portion 74 is removed from a case 70. Accordingly, in the case of FIG. 3, terminal portions 50c through 53c extend upward perpendicularly to the front surface of the semiconductor device 10. As illustrated in FIG. 1, the terminal portions 50c through 53c are bent after the lid portion 74 is fixed. Furthermore, the details of the structure of an A area enclosed by a thick dashed line in a circuit region 20a of the semiconductor device 10 of FIG. 3 will be described later in FIG. 5 and later drawings. The

A area is near a position in a planar view in which beam portions 72a and 72b connect.

The semiconductor device 10 includes a base plate 45 arranged on the back surface thereof and the case 70 which covers the sides and front surface thereof. Furthermore, the semiconductor device 10 includes components in a housing area 71e surrounded by the base plate 45 and the case 70. For example, an insulated circuit board 20 and a plurality of semiconductor chips (semiconductor chips 31 and 32) arranged over the insulated circuit board 20 are located in the housing area 71e.

The base plate 45 is rectangular in a planar view and has the shape of a plate. The base plate 45 may be a size smaller than the external shape of the case 70. Corner portions of the base plate 45 may be R-chamfered or C-chamfered. Furthermore, the thickness of the base plate 45 is greater than or equal to 0.5 mm and smaller than or equal to 5.0 mm. The base plate 45 is made of metal, such as copper, aluminum, or an alloy containing at least one of them, having an excellent heat dissipation property. In order to improve corrosion resistance, plating treatment may be performed on the surface of the base plate 45. The insulated circuit board 20 is bonded to the base plate 45 with a bonding member, such as solder, therebetween. In addition, an edge portion of the base plate 45 is bonded to a lower end of a frame portion of the case 70 with an adhesive or the like.

The insulated circuit board 20 includes a ceramic board 21, a plurality of circuit patterns (circuit patterns 22a and 22b) formed over the front surface of the ceramic board 21, and a metal plate 23 formed on the back surface of the ceramic board 21.

The ceramic board 21 is rectangular in a planar view and is made of a ceramic having high thermal conductivity. Such a ceramic is made of a material containing aluminum oxide, silicon nitride, aluminum nitride, or the like as a main ingredient. Furthermore, the thickness of the ceramic board 21 is greater than or equal to 0.2 mm and smaller than or equal to 2.0 mm. In addition, corner portions of the ceramic board 21 may be R-chamfered or C-chamfered.

The plurality of circuit patterns (circuit patterns 22a and 22b) are made of metal, such as copper, aluminum, or an alloy containing at least one of them, having good electrical conductivity. Furthermore, the thickness of the plurality of circuit patterns (circuit patterns 22a and 22b) is greater than or equal to 0.2 mm and smaller than or equal to 1.5 mm. In order to improve corrosion resistance, plating treatment may be performed on the surfaces of the plurality of circuit patterns (circuit patterns 22a and 22b).

At this time nickel, a nickel-phosphorus alloy, a nickel-boron alloy or the like is used as a plating material. The plurality of circuit patterns (circuit patterns 22a and 22b) are taken as an example. The number, shape, size, or the like of circuit patterns may properly be selected as needed.

Furthermore, the plurality of semiconductor chips (semiconductor chips 31 and 32) and external connection terminals 50 through 53 are properly connected to the plurality of circuit patterns (circuit patterns 22a and 22b) mechanically and electrically.

The metal plate 23 is made of a material containing metal, such as copper, aluminum, or an alloy containing at least one of them, having high thermal conductivity as a main ingredient. In order to improve the corrosion resistance of the metal plate 23, plating treatment may be performed. At this time nickel, a nickel-phosphorus alloy, a nickel-boron alloy or the like is used as a plating material.

A direct copper bonding (DCB) substrate, an active metal brazed (AMB) substrate, or the like may be used as the insulated circuit board 20 including the above parts. Furthermore, four circuit regions 20a through 20d are set on the front surface of the insulated circuit board 20. A plurality of circuit patterns are formed so that a determined circuit will be made up in each of the circuit regions 20a through 20d. In addition, a semiconductor chip including a switching element and a semiconductor chip including a diode element are mounted over a circuit pattern with solder therebetween in each of the circuit regions 20a through 20d. The arrangement of a circuit pattern and a semiconductor chip in each of the circuit regions 20a through 20d is not illustrated. Moreover, Pb-free solder is used as the solder. For example, Pb-free solder contains at least one of a tin-silver-copper alloy, a tin-zinc-bismuth alloy, a tin-copper alloy, and a tin-silver-indium-bismuth alloy as a main ingredient. A sintered metal body may be used in place of the solder. A sintered metal body is made of silver, gold, nickel, copper, or an alloy contained at least one of them.

Furthermore, with the insulated circuit board 20 over which the semiconductor chips are mounted, semiconductor chips are connected mechanically and electrically by a wire, a semiconductor chip and a circuit pattern are connected mechanically and electrically by a wire, and circuit patterns are connected mechanically and electrically by a wire. A wire is connected to a control electrode or a main electrode (emitter electrode) of each semiconductor chip. In addition, the semiconductor chips or the circuit patterns are connected mechanically and electrically to the external connection terminals 50 through 53 and control terminals 60 through 67 as needed with wires or solder.

The wires used for making the above connections are made of a material, such as gold, silver, copper, aluminum, or an alloy containing at least one of them, having good electrical conductivity. Furthermore, if wires are connected to the control electrodes of the semiconductor chips, then the diameter of the wires is, for example, greater than or equal to 20 μm and smaller than or equal to 300 μm. If wires are connected to the main electrodes of the semiconductor chips and are used for main current wiring, then the diameter of the wires is, for example, greater than or equal to 350 μm and smaller than or equal to 500 μm.

One end portions of the external connection terminal 50 through 53 are properly connected mechanically and electrically to the determined circuit regions 20a through 20d of the insulated circuit board 20 with solder therebetween. The terminal portion 50c, which is the other end portion of the external connection terminal 50, the terminal portions 51c and 52c, which are the other end portions of the external connection terminals 51 and 52 respectively, and the terminal portion 53c, which is the other end portion of the external connection terminal 53, are bonded to beam portions 72a, 72f, and 72b, respectively, described later inside the case 70, extend upward, and are exposed from the lid portion 74 of the case 70 described later.

One end portions of the control terminals 60 through 67 are properly connected electrically and mechanically (via wires if circumstances require) to semiconductor chips and circuit patterns in the circuit regions 20a through 20c in the housing area 71e. Connection terminal portions 60a through 66a, which are the other end portions of the control terminals 60 through 66 respectively, and a connection terminal portion 67a, which is the other end portion of the control terminal 67, are exposed from control terminal blocks 73c and 73d, respectively, of the case 70 described later.

The above external connection terminals 50 through 53 and control terminals 60 through 67 are made of metal, such as copper, aluminum, or an alloy containing at least one of them, having good electrical conductivity. Furthermore, in order to improve the corrosion resistance of the external connection terminals 50 through 53 and the control terminals 60 through 67, plating treatment may be performed. At this time nickel, a nickel-phosphorus alloy, a nickel-boron alloy, or the like is used as a plating material.

The plurality of semiconductor chips (semiconductor chips 31 and 32) arranged over the insulated circuit board 20 will be described. For example, two kinds of semiconductor chips are mounted in each of the circuit regions 20a through 20d of the insulated circuit board 20. One semiconductor chip is a switching element made of silicon or silicon carbide. The switching element is an IGBT, a power MOSFET, or the like. If the semiconductor chip is an IGBT, then the semiconductor chip has a collector electrode as a main electrode on the back surface and has a gate electrode as a control electrode and an emitter electrode as a main electrode on the front surface. If the semiconductor chip is a power MOSFET, then the semiconductor chip has a drain electrode as a main electrode on the back surface and has a gate electrode as a control electrode and a source electrode as a main electrode on the front surface.

Furthermore, the other semiconductor chip is a diode element made of silicon or silicon carbide. The diode element is a free wheeling diode (FWD) such as a Schottky barrier diode (SBD) or a P-intrinsic-N (PiN) diode. The semiconductor chip has a cathode electrode as a main electrode on the back surface and has an anode electrode as a main electrode on the front surface.

A semiconductor chip including a switching element which is a reverse conducting (RC)-IGBT may be arranged in place of the above semiconductor chip including a switching element and the above semiconductor chip including a diode element. With the RC-IGBT an IGBT and an FWD are included in one chip. In this case, a semiconductor chip including an RC-IGBT and a circuit pattern are connected mechanically and electrically by wires.

The case 70 will now be described. The case 70 includes a frame portion 71, beam portions 72a through 72h, and the lid portion 74. The frame portion 71 has the shape of a rectangular frame in a planar view and includes inner wall surfaces 71a through 71d which surround the housing area 71e on all sides, fixing portions 73a, and the control terminal blocks 73c and 73d located adjacently to the backs of the inner wall surfaces 71a and 71c respectively (see FIG. 3 in particular).

The beam portions 72a through 72h are formed so as to extend parallel to the front surface of the insulated circuit board 20. The beam portions 72a through 72h are formed so as to extend inward perpendicularly to the inner wall surfaces 71a through 71d included in the frame portion 71. Each of the beam portions 72a through 72h has the shape of a bar. The beam portions 72a and 72b extend perpendicularly to the inner wall surfaces 71a and 71b, respectively, which intersect at right angles. The beam portions 72a and 72b are connected in a position in which they intersect. The beam portions 72c and 72d extend perpendicularly to the inner wall surfaces 71b and 71c, respectively, which intersect at right angles. The beam portions 72c and 72d are connected in a position in which they intersect. The beam portion 72f is formed parallel to the inner wall surfaces 71b and 71d opposite each other so as to extend from the inner wall surfaces 71c and 71a and support the inner wall surfaces 71c and 71a opposite each other. The beam portion 72e is formed parallel to the inner wall surfaces 71a and 71c so as to extend from the beam portions 72d and 72f and support the beam portions 72d and 72f. The beam portions 72g and 72h are formed parallel to the inner wall surfaces 71a and 71c so as to extend from the inner wall surface 71d and the beam portion 72f and support the inner wall surface 71d and the beam portion 72f. The beam portions 72a and 72f are formed at approximately the same intervals with respect to the width of the inner wall surface 71a. The beam portions 72g and 72h are formed at approximately the same intervals with respect to the width of the inner wall surface 71d. Furthermore, the beam portions 72a through 72f are formed so as to be on the same plane as the front surface of the frame portion 71 is. In addition, the thickness (length in the direction perpendicular to the front surface of the insulated circuit board 20, that is to say, in the Z direction) of the beam portions 72a through 72f may be uniform. The width (length in a planar view) of the beam portions 72a through 72f is properly set according to positions in which they are formed. Moreover, the external connection terminals 50 through 53 are bonded to the above beam portions 72a through 72h. The external connection terminals 50 through 53 may be integrally molded with the beam portions 72a through 72h.

The lid portion 74 is located over the housing area 71e of the frame portion 71 and stops up the housing area 71e. Furthermore, terminal blocks 74a through 74d are formed on the front surface of the lid portion 74. The terminal portions 50c through 53c of the external connection terminals 50 through 53 are exposed from the terminal blocks 74a through 74d respectively. The terminal portions 50c, 51c and 52c, and 53c of the external connection terminals 50 through 53 extending from the beam portions 72a, 72f, and 72d perpendicularly to the beam portions 72a, 72f, and 72d respectively are inserted into the terminal blocks 74a through 74d respectively and are bent. By doing so, the terminal portions 50c through 53c of the external connection terminals 50 through 53 are arranged on the terminal blocks 74a through 74d respectively.

Furthermore, the case 70 may include the fixing portions 73a. Each of the fixing portions 73a has the shape of an approximately flat plate. The fixing portions 73a are formed in the four corners outside the inner wall surfaces 71a through 71d which surround the housing area 71e on all sides. A fixing hole 73b which penetrates each fixing portion 73a is made. The control terminal block 73c is located between a pair of fixing portions 73a on the side of the back of the inner wall surface 71a. The connection terminal portions 60a through 66a of the control terminals 60 through 66, respectively, extend upward perpendicularly to the front surface of the control terminal block 73c. The control terminal block 73d is located between a pair of fixing portions 73a on the side of the back of the inner wall surface 71c. The connection terminal portion 67a of the control terminal 67 extends upward perpendicularly to the front surface of the control terminal block 73d.

With the above case 70 the frame portion 71 and the lid portion 74, together with the external connection terminals 50 through 53 and the control terminals 60 through 67, are integrally molded by insert molding by the use of a thermoplastic resin such as polyphenylene sulfide resin, polybutylene terephthalate resin, polybutylene succinate resin, polyamide resin, or acrylonitrile butadiene styrene resin.

With the semiconductor device 10 including the above components, the housing area 71e of the case 70 is filled with a sealing member over the base plate 45. The sealing member is an insulating polymer gel. Silicone gel is preferably contained as a main ingredient. The details of the sealing member will be described later.

A cooling unit may be arranged on the back surface of the above semiconductor device 10. The cooling unit is a heat sink including a plurality of fins, a cooler using a refrigerant, or the like. Furthermore, the cooling unit is fixed onto the back surface of the semiconductor device 10 with thermal grease, such as silicone with which metal oxide filler is mixed, therebetween. A heat radiation base plate and a heat sink are made of metal, such as aluminum, iron, silver, copper, or an alloy containing at least one of them, having high thermal conductivity. In order to improve corrosion resistance, plating treatment may be performed on the surfaces of the heat radiation base plate and the heat sink. At this time nickel, a nickel-phosphorus alloy, a nickel-boron alloy, or the like is used as a plating material.

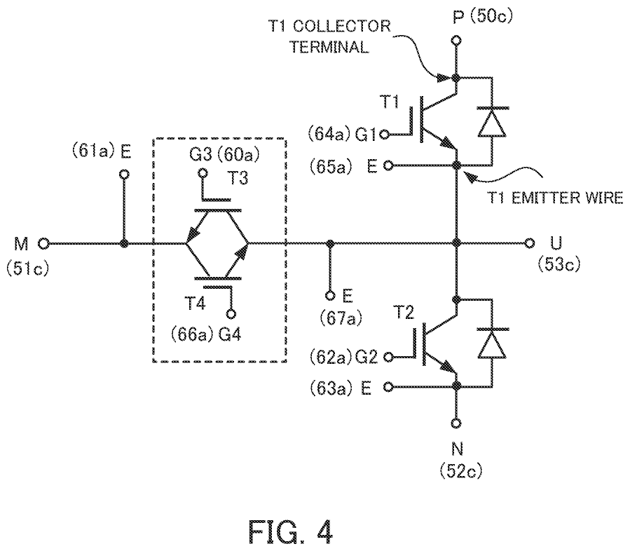

An equivalent circuit which realizes the power conversion function of the semiconductor device 10 will now be described by the use of FIG. 4 (and FIG. 1 and FIGS. 2A and 2B). FIG. 4 illustrates an equivalent circuit of the function of the semiconductor device according to the embodiment. The semiconductor device 10 includes semiconductor chips including switching elements and diode elements and circuit patterns in the case 70 and makes up an inverter circuit illustrated in FIG. 4. In FIG. 4, each of semiconductor chips T1 through T4 includes a switching element. Furthermore, the semiconductor chips including the switching elements and the diode elements are properly mounted in the circuit regions 20a through 20d.

A high potential terminal of an external power source is connected to the terminal portion 50c, which is a P terminal, and a low potential terminal of the external power source is connected to the terminal portion 52c, which is an N terminal. Furthermore, an intermediate potential terminal of the external power source is connected to the terminal portion 51c, which is an M terminal. In addition, a load (not illustrated) is connected to the terminal portion 53c, which is a U terminal (output terminal). As a result, the semiconductor device 10 functions as a three-level inverter.

With the three-level inverter the following operations are performed. If the polarity of an output voltage is positive, usually the connection terminal portions 64a and 60a connected to control electrodes of the semiconductor chips T1 and T3 respectively are alternately turned on and off, the connection terminal portion 66a connected to a control electrode of the semiconductor chip T4 is always kept in an on state, and the connection terminal portion 62a connected to a control electrode of the semiconductor chip T2 is always kept in an off state. Conversely, if the polarity of an output voltage is negative, the semiconductor chips T2 and T4 are alternately turned on and off, the semiconductor chip T3 is always kept in an on state, and the semiconductor chip T1 is always kept in an off state.

With a collector electrode (T1 collector terminal) of the semiconductor chip T1 an input voltage from the external power source is applied to the terminal portion 50c, which is a P terminal. Furthermore, for example, if, as stated above, a positive voltage is outputted, then an on signal is provided to the control electrode (connection terminal portion 64a) of the semiconductor chip T1. As a result, a current is outputted from an emitter electrode on the front surface of the semiconductor chip T1 and this current is an output current. The current outputted from the emitter electrode of the semiconductor chip T1 is outputted via a T1 emitter wire connected to the emitter electrode and described later from the terminal portion 53c, which is a U terminal.

Furthermore, an intermediate voltage from the external power source is applied from the terminal portion 51c, which is an M terminal, to a collector electrode of the semiconductor chip T4. In addition, when the connection terminal portion 64a, which is the control electrode of the semiconductor chip T1, is put into an off state, the output current is commutated to the semiconductor chip T4, which is in an on state, and a current is outputted from an emitter electrode on the front surface of the semiconductor chip T4. The current outputted from the emitter electrode of the semiconductor chip T4 is outputted from the terminal portion 53c, which is a U terminal.

Furthermore, the load is connected from the terminal portion 53c, which is a U terminal, to a collector electrode of the semiconductor chip T2. If the inverter outputs a negative voltage, a current is outputted from an emitter electrode on the front surface of the semiconductor chip T2 when the connection terminal portion 62a, which is a control electrode of the semiconductor chip T2, is put into an on state. The current outputted from the emitter electrode of the semiconductor chip T2 is outputted from the terminal portion 52c, which is an N terminal.

Furthermore, the load is connected from the terminal portion 53c, which is a U terminal, to a collector electrode of the semiconductor chip T3. In addition, when the connection terminal portion 62a connected to control electrode of the semiconductor chip T2 is put into an off state, the output current is commutated to the semiconductor chip T3 which is in an on state. A current outputted from an emitter electrode of the semiconductor chip T3 is outputted from the terminal portion 51c, which is an M terminal.

The semiconductor device 10 properly controls each of the above operations. By doing so, semiconductor device 10 converts direct-current power inputted from the external power source to alternating-current power with great efficiency. The connection terminal portions 65a, 63a, 61a, and 67a, each of which is a sense emitter terminal E, have the function of detecting an emitter current outputted from the semiconductor chips T1 through T4 respectively. Accordingly, each of the connection terminal portions 65a, 63a, 61a, and 67a detects an overcurrent on the basis of a detected emitter current.

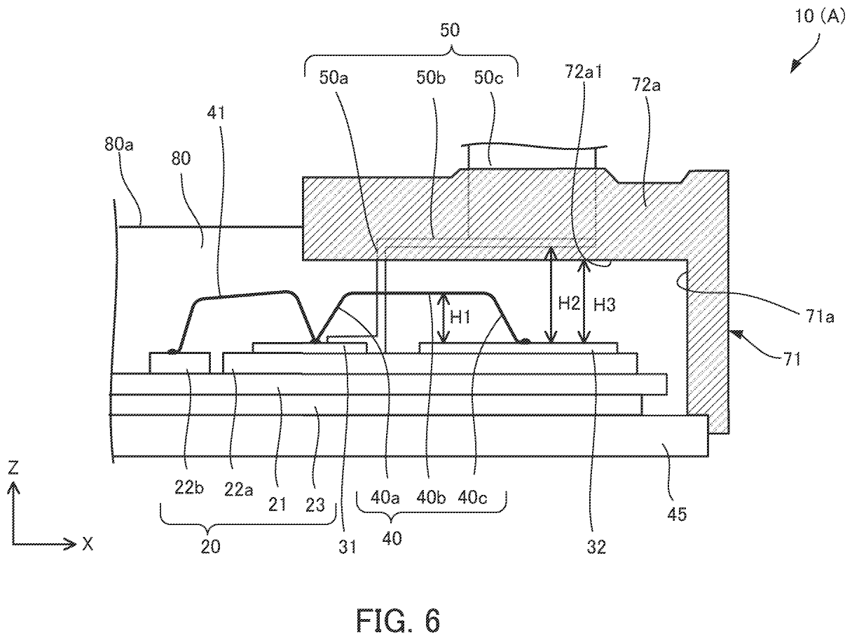

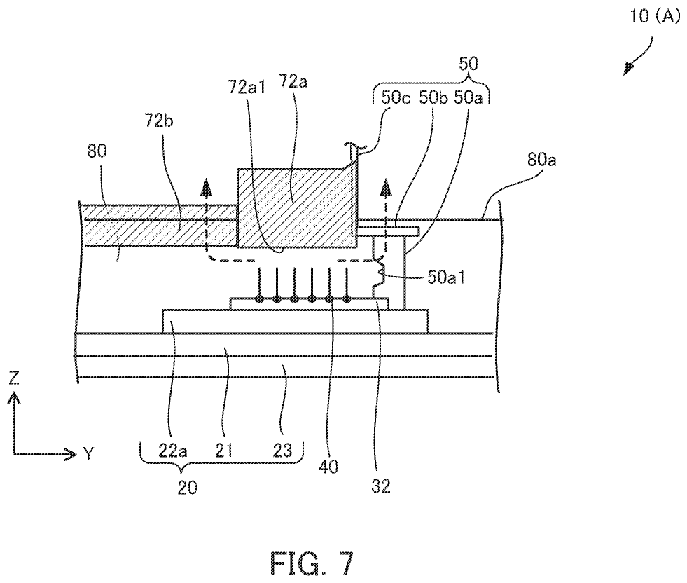

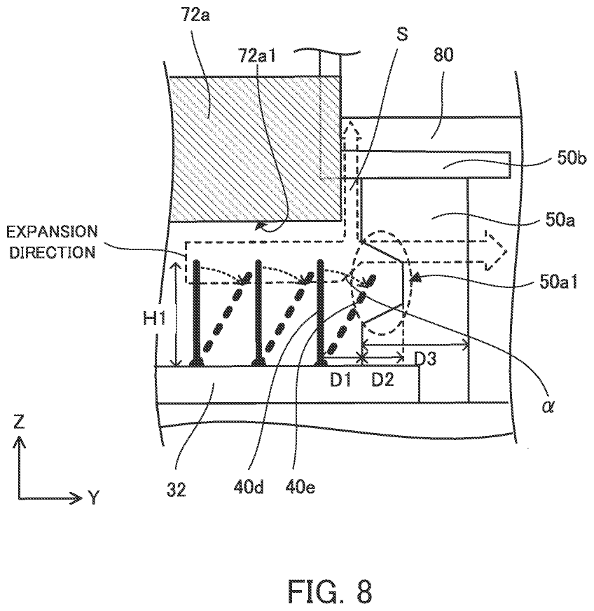

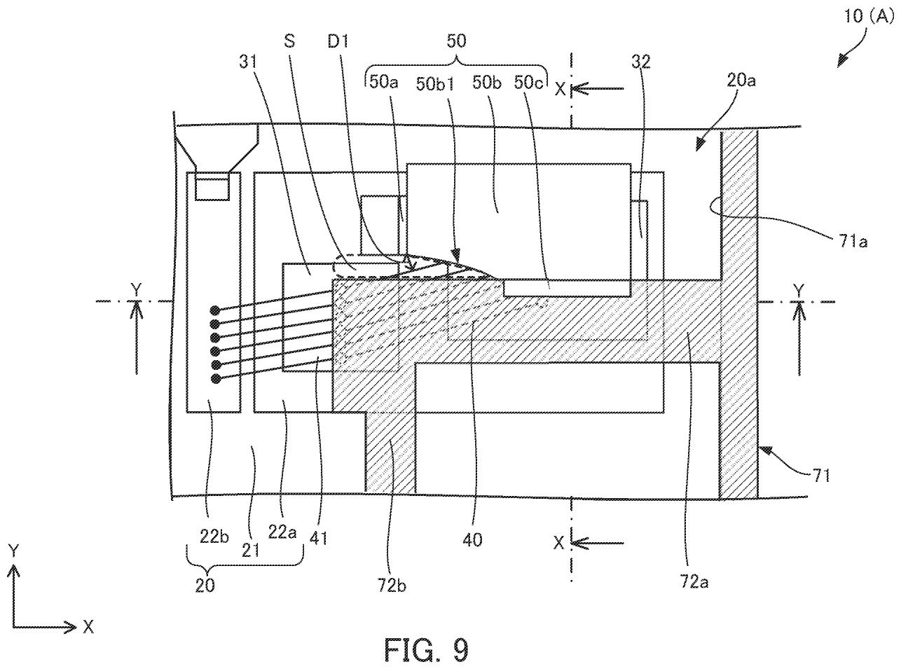

The structure of the A area illustrated in FIG. 3 and enclosed by a thick dashed line in the circuit region 20a of the semiconductor device 10 will now be described by the use of FIGS. 5 through 9. FIG. 5 is a fragmentary plan view of the semiconductor device according to the embodiment. Furthermore, FIGS. 6 through 8 are fragmentary sectional views of the semiconductor device according to the embodiment. FIG. 9 is another fragmentary plan view of the semiconductor device according to the embodiment. FIG. 6 is a sectional view taken along the dot-dash line Y-Y of FIG. 5. FIG. 7 is a sectional view taken along the dot-dash line X-X of FIG. 5. In addition, FIG. 8 is an enlarged view of the vicinity of the wire 40 of FIG. 7.

The semiconductor chips 31 and 32 and the external connection terminal 50 are mounted over the circuit pattern 22a of the insulated circuit board 20 in the A area of the semiconductor device 10. Furthermore, the main electrodes (emitter electrodes) on the front surfaces of the semiconductor chips 31 and 32 are connected by wires 40 and the main electrode on the front surface of the semiconductor chip 31 and the circuit pattern 22a are connected by wires 41. That is to say, the wires 40 and 41 are wirings for an input current or an output current, which is a main current. The direction in which the wires 40 and 41 are wired is approximately perpendicular to the inner wall surface 71a. In addition, the beam portions 72a and 72b are arranged over the insulated circuit board 20.

One end portions and the other end portions of the wires 40 and 41 are bonded to the semiconductor chip 31 or 32 or the circuit pattern 22a by ultrasonic vibration. Each of the wires 40 and 41 is wired over the insulated circuit board 20 and the semiconductor chips 31 and 32 between the one end portion and the other end portion at a determined distance H1 from the semiconductor chip 31 or 32. For example, each wire 40 includes a first portion 40a, a second portion 40b, and a third portion 40c. One end portion of the first portion 40a is bonded to the main electrode of the semiconductor chip 31, rises at a determined angle to the front surface of the insulated circuit board 20, and extends. The second portion 40b extends from the first portion 40a which rises and extends approximately parallel to the insulated circuit board (circuit pattern 22a). The third portion 40c falls at a determined angle from the second portion 40b to the semiconductor chip 32 and the other end portion of the third portion 40c is bonded to the main electrode of the semiconductor chip 32. Furthermore, the height H1 of the second portion 40b of the wire 40 from the semiconductor chips 31 and 32 is greater than or equal to 2.0 mm and smaller than or equal to 8.0 mm. In addition, the height H1 of the second portion 40b of the wire 40 from the semiconductor chips 31 and 32 is preferably greater than or equal to 4.5 mm and smaller than or equal to 5.5 mm.

The external connection terminal 50 integrally includes a leg portion 50a, a joint portion 50b, and a terminal portion 50c. The thickness of the whole of the external connection terminal 50 is uniform and is, for example, greater than or equal to 0.5 mm and smaller than or equal to 4.0 mm.

One end of the leg portion 50a is bonded to the front surface of the circuit pattern 22a and the other end of the leg portion 50a is electrically connected to the terminal portion 50c. A bonding portion of the one end of the leg portion 50a may be bent parallel to the circuit pattern 22a. The one end of the leg portion 50a is bonded to the front surface of the circuit pattern 22a by solder bonding or ultrasonic vibration. The leg portion 50a has an extending portion which extends upward from the bonding portion. The other end of the extending portion is connected via the joint portion 50b to the terminal portion 50c. The extending portion has the shape of a flat plate, is opposite the inner wall surface 71a, and extends perpendicularly to the front surface of the circuit pattern 22a. Furthermore, a side portion (side portion on the −Y side (see FIGS. 7 and 8)) of the extending portion of the leg portion 50a is located near a side portion of the wire 40 in a planar view. That is to say, the leg portion 50a is arranged at a determined distance D1 from the wire 40 in a planar view perpendicularly (in the Y direction, first direction) to the direction (X direction, second direction) of the wiring of the wire 40 to connect points at which the wire 40 is bonded to the semiconductor chips 31 and 32. In addition, the leg portion 50a is arranged in a planar view perpendicularly (in the Y direction) to the direction (X direction) of the wiring of the wire 40 to connect points at which the wire 40 is bonded to the semiconductor chips 31 and 32. The determined distance D1 is longer than or equal to 10 percent of the height H1 from the front surfaces of the semiconductor chips and 32 to the second portion 40b of the wire 40 and shorter than 100 percent of the height H1. Moreover, the determined distance D1 is more preferably longer than or equal to 30 percent of the height H1.

Furthermore, as illustrated in FIG. 6, the leg portion 50a extends upward from the front surface of the semiconductor chip 32, which is the bonding portion, to a height H2 by the extending portion. The height H2 is greater than or equal to 4.0 mm and smaller than or equal to 12.0 mm. Furthermore, the height H2 is greater than the height H1 which is the height of the second portion 40b of the wire 40 from the semiconductor chips 31 and 32. It is preferable that the height H1 be greater than or equal to 0.6 times the height H2 and smaller than or equal to 0.8 times the height H2. Accordingly, the leg portion 50a is arranged in a side view in a position in which the second portion 40b of the wire 40 is superimposed over the leg portion 50a. That is to say, the second portion 40b of the wire 40 may be arranged between the one end and the other end of the leg portion 50a.

Furthermore, a concave portion 50a1 is formed in a side of the leg portion 50a opposite the second portion 40b of the wire 40 (see FIGS. 7 and 8). That is to say, the concave portion 50a1 is formed in the side of the leg portion 50a at a level which is the same as that of the second portion 40b of the wire 40. The concave portion 50a1 is concave in a side of the extending portion having the shape of a flat plate and has the shape of a trapezoid. A depth D2 (length in the Y direction) of the concavity of the concave portion 50a1 may be greater than or equal to 10 percent of a width D3 (length in the Y direction) of the whole of the extending portion of the leg portion 50a and smaller than or equal to 50 percent of the width D3. If the depth D2 of the concavity of the concave portion 50a1 is smaller than 10 percent of the width D3, then the effect of contact suppression described later is small. In addition, if the depth D2 of the concavity of the concave portion 50a1 is greater than 50 percent of the width D3, then a main current does not properly flow. The shape of the concave portion 50a1 is not limited to a trapezoid. The concave portion 50a1 may have the shape of a circular arc or a wedge.

The joint portion 50b has the shape of a flat plate. One end of the joint portion 50b is connected to the other end of the leg portion 50a and the other end of the joint portion 50b is connected to the terminal portion 50c. The joint portion 50b extends from the other end of the leg portion 50a to the inner wall surface 71a and the beam portion 72a. The joint portion 50b may extend parallel to the insulated circuit board 20 (circuit pattern 22a). Furthermore, as illustrated in FIG. 5, a notch 50b1 is made in a planar view in a lower left-hand corner portion of the joint portion 50b. The notch 50b1 is between the joint portion 50b and the beam portion 72a. The notch 50b1 has the shape of a circular arc and is made from an end portion of the leg portion 50a on the side of the wire 40 (on the −Y side) to an end portion of the terminal portion 50c on the side of the leg portion 50a (on the −X side) so as to be concave toward the inside of the joint portion 50b. The joint portion 50b and the beam portion 72a are partially separated from each other by the notch 50b1. As described later, the beam portion 72a is situated over part of the wire 40. The notch 50b1 may form a straight line which connects the end portion of the leg portion 50a on the side of the wire 40 (on the −Y side) and the end portion of the terminal portion 50c on the side of the leg portion 50a (on the −X side) or be concave toward the inside of the joint portion 50b. The notch 50b1 may have a fan or rectangular shape in a planar view. The area of the notch 50b1 is preferably set so that a current will properly flows through the joint portion 50b and so that the strength of the joint portion 50b will not deteriorate.

The terminal portion 50c has the shape of a flat plate. One end of the terminal portion 50c is connected to the other end of the joint portion 50b and extends upward perpendicularly to the front surface of the insulated circuit board 20 (circuit pattern 22a). The terminal portion 50c is opposite the inner wall surfaces 71b and 71d (see FIG. 3). Therefore, as illustrated in FIG. 7, the joint portion 50b and the terminal portion 50c form the shape of the letter “L”. Furthermore, the terminal portion 50c is inserted into the terminal block 74a formed on the lid portion 74 of the case 70 and is bent. As a result, the other end of the terminal portion 50c is arranged on the terminal block 74a (see FIG. 1 and FIGS. 2A and 2B).

The beam portion 72a extends from the inner wall surface 71a perpendicularly thereto in a planar view. The beam portion 72a intersects with the beam portion 72b which extends in the same way from the inner wall surface 71b and is connected to the beam portion 72b. The beam portion 72b extends from a position on the inner wall surface 71b corresponding to the leg portion 50a perpendicularly to the inner wall surface 71b. Accordingly, the beam portion 72a extends from the inner wall surface 71a to the vicinity of the side of the leg portion 50a. The beam portion 72a may extend through the vicinity of the side of the leg portion 50a to the side of the inner wall surface 71c. For example, the beam portion 72a may extend further to the side of the inner wall surface 71c and be situated over at least part of the wire 41. Furthermore, the terminal portion 50c of the external connection terminal 50 is integrally molded with a side of the beam portion 72a on the side of the inner wall surface 71d (on the +Y side). At this time an opposite surface 72a1 of the beam portion 72a is below the joint portion 50b (see FIG. 6 and FIG. 7). Both of the beam portions 72a and 72b are located the same distance apart from the insulated circuit board 20. A height H3 of the opposite surface 72a1 of the beam portion 72a opposite the insulated circuit board 20 from the front surfaces of the semiconductor chips 31 and 32 is greater than or equal to 3.5 mm and smaller than or equal to 7.5 mm. As illustrated in FIG. 5 and FIG. 6, the beam portion 72a is situated over part of the circuit pattern 22a, part of the front surfaces of the semiconductor chips 31 and 32, and part of the wire 40. That is to say, in FIG. 6, the opposite surface 72a1 of the beam portion 72a opposite the insulated circuit board 20 is over the wire 40, the front surfaces of the semiconductor chips 31 and 32, and the front surface of the insulated circuit board 20 and is apart therefrom.

Therefore, in the case of FIG. 5, the beam portion 72a extends approximately parallel to the direction in which the wire 40 is wired and is situated over the second portion 40b of the wire 40 (see FIG. 6 and FIG. 7). On the other hand, the beam portion 72a does not always extend approximately parallel to the direction in which the wire 40 is wired, depending on the arrangement of the semiconductor chips 31 and 32 to which the wire 40 is connected. As illustrated in FIG. 9, for example, the positions of semiconductor chips 31 and 32 may deviate in the Y direction from those of the semiconductor chips 31 and 32 illustrated in FIG. 5. If the semiconductor chips 31 and 32 are mounted over a circuit pattern 22a in this state, then the direction in which a wire 40 is wired also forms an angle with the beam portion 72a. In this case, as illustrated in FIG. 8 (and FIG. 6), the beam portion 72a is also situated over part of the circuit pattern 22a, part of the semiconductor chips 31 and 32, and part (second portion 40b in particular) of the wire 40.

Furthermore, as stated above, the case 70 is filled with a sealing member 80. That is to say, the sealing member 80 seals the semiconductor chips 31 and 32 over the insulated circuit board 20 and the wires 40 and 41. The case 70 is filled with the sealing member 80 so that a sealing surface 80a, which is the upper surface of the sealing member 80, will be above the opposite surface 72a1 of the beam portion 72a. Furthermore, the sealing surface 80a is above the back surface of the joint portion 50b of the external connection terminal 50. In this embodiment the joint portion 50b is sealed with the sealing member 80 (FIG. 7). The case 70 is filled with the sealing member 80 so that the sealing surface 80a will be below the upper surface of the beam portion 72a. Accordingly, as illustrated in FIG. 5, the sealing surface 80a of the sealing member 80 is exposed from between the beam portion 72a, the leg portion 50a of the external connection terminal 50, and the notch 50b1 of the joint portion 50b (from an S area illustrated in FIG. 5).

The expansion of the sealing member 80 and the movement of the wire 40 at the time of the operation of the semiconductor device 10 will now be described by reference to FIG. 7 and FIG. 8. When the semiconductor chips 31 and 32 operate, they generate heat. When the sealing member 80 is heated due to heat generated by the semiconductor chips 31 and 32, the sealing member 80 expands in all directions. At this time the expansion of the sealing member 80 in an upward direction (to the +Z side) is suppressed by the opposite surface 72a1 of the beam portion 72a. Furthermore, the movement of the wire 40 in an upward direction caused by the expansion of the sealing member 80 is also suppressed. This prevents the wire 40 from peeling (breaking) off the semiconductor chips 31 and 32 in an upward direction.

Internal stress generated in the sealing member 80 whose expansion in the upward direction is suppressed in this way by the opposite surface 72a1 of the beam portion 72a increases. As a result, the sealing member 80 whose expansion in the upward direction is suppressed by the opposite surface 72a1 of the beam portion 72a expands in a planar view perpendicularly to the direction in which the beam portion 72a extends (to the sides of the inner wall surfaces 71b and 71d, that is to say, to the ±Y sides). The wire 40 is swung horizontally as a result of the expansion of the sealing member 80 to both sides of the beam portion 72a and falls to both sides of the beam portion 72a. On the other hand, an upper portion of the beam portion 72a is exposed on the side of the inner wall surface 71d (on the +Y side) because of the presence of the S area. Accordingly, part of the sealing member 80 expands in the upward direction (in the direction indicated by the dashed arrow in FIG. 7 or FIG. 8). As a result, a horizontal swing of the wire 40 is suppressed beyond the S area (on the +Y side). That is to say, the wire 40 does not fall beyond the S area and the wire 40 falls only to a determined angle α. The determined angle α is 45 degrees or less. The determined angle α is preferably 30 degrees or less.

Furthermore, the upper portion of the beam portion 72a is also exposed on the side of the inner wall surface 71b (on the −Y side). Part of the sealing member 80 expands in the upward direction (in the direction indicated by the left-hand dashed arrow in FIG. 7). As a result, a horizontal swing of the wire 40 is suppressed beyond an area covered with the beam portion 72a (on the −Y side). Accordingly, the wire 40 also falls only to the determined angle a on the side of the inner wall surface 71b (on the −Y side). In this case, the determined angle α is also 45 degrees or less. The determined angle α is preferably 30 degrees or less.

As has been described, with the semiconductor device 10 according to the embodiment a short circuit caused by contact between the wire 40 and the external connection terminal 50 or a fall of the wire 40 or the breaking of the wire 40 from the semiconductor chip 31 or 32 is suppressed.

If the width of the beam portion 72a is too great, then the wire 40 is significantly swung horizontally. As a result, the wire 40 falls to an angle greater than the determined angle α. This may lead to a short circuit or breaking of the wire 40 from the semiconductor chip 31 or 32. Accordingly, as stated above, there is a gap in a planar view between an edge portion on the side of the inner wall surface 71d (on the +Y side) of the width (in the Y direction in FIG. 5) of the beam portion 72a and the leg portion 50a. Furthermore, an edge portion on the side of the inner wall surface 71b (on the −Y side) of the width (in the Y direction in FIG. 5) of the beam portion 72a may be broadened in a planar view to the vicinity of an edge portion on the side of the inner wall surface 71b (on the −Y side) of the circuit pattern 22a. It is preferable that the edge portion on the side of the inner wall surface 71d (on the +Y side) of the beam portion 72a and the edge portion on the side of the inner wall surface 71b (on the −Y side) of the beam portion 72a be equal in length in the range of ±10% with the central point of all of the plurality of wires 40 as a center in the direction of the width (in the Y direction) of the beam portion 72a.

Furthermore, the leg portion 50a is located on the side of the S area. As a result, the expansion of the sealing member 80 from the beam portion 72a to the side of the inner wall surface 71d (to the +Y side) is prevented by the leg portion 50a. This stimulates the expansion of the sealing member 80 further to an area over the S area. Accordingly, the sealing member 80 expands more reliably in an upward direction (to the S area). This suppresses a horizontal swing of the wire 40 further.

Furthermore, the concave portion 50a1 is formed in the side of the leg portion 50a opposite the second portion 40b of the wire 40. Even if the wire 40 swings to the side of the external connection terminal 50 as a result of the expansion of the sealing member 80, contact between the wire 40 and the leg portion 50a is avoided more reliably by the presence of the concave portion 50a1 of the leg portion 50a. This prevents a short circuit between the wire 40 and the external connection terminal 50.

Even in the case of FIG. 9, the beam portion 72a is situated over the wire 40 (second portion 40b) opposite the side of the leg portion 50a. This suppresses a swing of the wire 40 to both sides of the beam portion 72a. This is the same with the above case. In particular, contact between the wire 40 and the leg portion 50a is suppressed.

The above semiconductor device 10 includes the insulated circuit board 20 including the ceramic board 21, the circuit pattern 22a formed over the front surface of the ceramic board 21, the semiconductor chips 31 and 32 arranged over the front surface of the circuit pattern 22a, and the wire 40 connected to the front surfaces of the semiconductor chips 31 and 32 and is wired. Furthermore, the semiconductor device 10 includes the external connection terminal 50. The external connection terminal 50 includes the leg portion 50a and the terminal portion 50c. One end of the leg portion 50a is bonded to the front surface of the circuit pattern 22a. The leg portion 50a extends perpendicularly to the front surface of the circuit pattern 22a. Part of the leg portion 50a is opposite a side portion of the wire 40. The terminal portion 50c is electrically connected to the other end of the leg portion 50a. In addition, the semiconductor device 10 includes the case 70. The case 70 includes the frame portion 71 which surrounds the insulated circuit board 20 and the beam portion 72a which is bonded to the external connection terminal 50 and which is situated over at least part of the wire 40. Moreover, the semiconductor device 10 includes the sealing member 80. The case 70 is filled with the sealing member 80. The sealing member 80 seals the front surface of the insulated circuit board 20, the semiconductor chips 31 and 32, the wire 40, and the back surface of the beam portion 72a and is exposed in a planar view from the gap (S area) between the leg portion 50a and the beam portion 72a.

As a result, the sealing member 80 heated due to heat generated by the semiconductor chips 31 and 32 expands in the directions of both side portions of the beam portion 72a and expands in an upward direction. This suppresses a horizontal swing of the wire 40 to both sides of the beam portion 72a in a planar view. As a result, contact between the wire 40 and the external connection terminal 50 is suppressed and a short circuit is prevented. Accordingly, a swing of the wire 40 in the case 70 caused by a change in temperature is reduced and deterioration in the reliability of the semiconductor device 10 is suppressed.

According to the disclosed technique, a swing of a wire in a case caused by a change in temperature is reduced and deterioration in the reliability of a semiconductor device is suppressed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an insulated circuit board including an insulating plate and a circuit pattern formed on a front surface of the insulating plate;
a semiconductor chip disposed on a front surface of the circuit pattern;
a wire connected to a front surface of the semiconductor chip;
an external connection terminal including
a leg portion having one end bonded to the front surface of the circuit pattern, extending perpendicularly to the front surface of the circuit pattern, and facing the wire in a first direction perpendicular to a second direction in which the wire extends, and
a terminal portion electrically connected to an other end of the leg portion;
a case including
a frame portion which surrounds the insulated circuit board, and
a beam portion bonded to the external connection terminal with a gap between the leg portion and the beam portion and overlapping at least a part of the wire in a plan view of the semiconductor device; and
a sealing member with which the case is filled, which
seals a front surface of the insulated circuit board, the semiconductor chip, the wire, and a back surface of the beam portion, and
is exposed from the gap between the leg portion and the beam portion, in the plan view.

2. The semiconductor device according to claim 1, wherein a portion of the wire that faces the leg portion overlaps the beam portion in the plan view.

3. The semiconductor device according to claim 2, wherein:
the insulated circuit board has a bonded portion;
the wire has one end connected to the front surface of the semiconductor chip and an other end connected to the bonded portion of the insulated circuit board, and includes a first portion, a second portion, and a third portion, which continue between the one end and the other end;
the first portion rises and extends from the one end in at a determined angle;
the second portion extends approximately in parallel to the circuit pattern from the first portion; and
the third portion falls from the second portion at a determined angle and is bonded to the bonded portion at the other end.

4. The semiconductor device according to claim 3, wherein:
the leg portion, in the plan view, is arranged at a determined distance in the first direction apart from the second portion of the wire; and
the determined distance is in a range of 10 percent to 100 percent of a height of the second portion of the wire from the front surface of the semiconductor chip.

5. The semiconductor device according to claim 4, wherein the leg portion has two sides parallel to each other and perpendicular to the front surface of the circuit pattern, and has a concave portion at one of the two sides that is closer to the wire than is the other of the two sides.

6. The semiconductor device according to claim 5, wherein the concave portion and the second portion are formed at a same level from the front surface of the circuit pattern.

7. The semiconductor device according to claim 5, wherein the concave portion is recessed from the one of the two sides toward the other of the two sides in a depth direction perpendicular to each of the two sides, and a depth of a concavity of the concave portion in the depth direction is in a range of 10 percent and 50 percent of a width of the leg portion.

8. The semiconductor device according to claim 4, wherein the external connection terminal further includes a joint portion which connects an upper end of the leg portion and a lower end of the terminal portion and which extends in a direction parallel to the circuit pattern.

9. The semiconductor device according to claim 8, wherein a lower surface of the joint portion is positioned closer than a sealing surface of the sealing member to the front surface of the circuit pattern.

10. The semiconductor device according to claim 8, wherein in the plan view the sealing member is exposed from the gap between the beam portion and the joint portion.

11. The semiconductor device according to claim 8, wherein a height of the second portion of the wire from the front surface of the circuit pattern is in a range of 0.6 times and 0.8 times a height of the joint portion of the external connection terminal from the front surface of the semiconductor chip.

12. The semiconductor device according to claim 8, wherein the back surface of the beam portion is positioned closer than a back surface of the joint portion of the external connection terminal to the front surface of the circuit pattern.

13. The semiconductor device according to claim 1, wherein the terminal portion of the external connection terminal and the beam portion of the case are a one-piece molding.

14. The semiconductor device according to claim 1, wherein the sealing member contains polymer gel as a main ingredient.

15. A semiconductor device, comprising:
an insulated circuit board including an insulating plate and a circuit pattern formed on a front surface of the insulating plate, and having a first bonded portion and a second bonded portion;
a wire connecting the first bonded portion and the second bonded portion of the insulated circuit board;
an external connection terminal including
a leg portion bonded to a front surface of the circuit pattern at a side of the wire, and extending perpendicularly to the front surface of the circuit pattern and
a terminal portion electrically connected to the leg portion;
a case including
a frame portion which surrounds the insulated circuit board, and
a beam portion that extends from an inner wall surface of the frame portion to a vicinity of the leg portion so that a gap is formed between the beam portion and the leg portion, and overlaps at least a part of the wire in a plan view of the semiconductor device; and
a sealing member with which the case is filled, which
covers a front surface of the insulated circuit board, the first bonded portion, the second bonded portion, and the wire,
has a sealing surface positioned farther from the front surface of the circuit pattern than is a surface of the beam portion facing the circuit pattern, and
in the plan view, is exposed from the gap between the leg portion and the beam portion.
